(19) United States
(12) Patent Application Publication
(10) Pub. No.: US 2022/0302856 A1
(43) Pub. Date: Sep. 22, 2022

(54) Floor Mat Electrical Generator Apparatus

(71) Applicant: Alec Daniels, Denver, CO (US)

(72) Inventor: Alec Daniels, Denver, CO (US)

(21) Appl. No.: 17/204,555

(22) Filed: Mar. 17, 2021

(51) Int. Cl. H02N 2/18; H01L 41/047; H01R 13/62; A47G 27/02

(52) U.S. Cl. CPC H02N 2/186; H01L 41/0475; H01R 13/6205; A47G 27/0293; A47G 27/0237

(57) ABSTRACT

A floor mat electrical generator system for generating electricity when users walk or dance on flooring includes a plurality of mat tiles and a power collection terminal. Each mat tile comprises a mat body having a body top side, a body bottom side, a body left side, and a body right side with a male protrusion portion and a female recessed portion to engage the adjacent mat tile. A plurality of kinetic generators is coupled to the mat body. A plurality of electrical connectors is coupled to the mat body and is in operational communication with the plurality of kinetic generators and with the plurality of electrical connectors of the adjacent mat tiles. The power collection terminal comprises a connector selectively engageable with a corner mat tile of the plurality of mat tiles and a power bank to store energy generated by the plurality of kinetic generators.

### CROSS-REFERENCE TO RELATED APPLICATIONS

Not Applicable

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC OR AS A TEXT FILE VIA THE OFFICE ELECTRONIC FILING SYSTEM

Not Applicable

### STATEMENT REGARDING PRIOR DISCLOSURES BY THE INVENTOR OR JOINT INVENTOR

Not Applicable

### BACKGROUND OF THE INVENTION

### (1) Field of the Invention

The disclosure relates to generator devices and more particularly pertains to a new generator device for generating electricity when users walk or dance on flooring. The present device includes a plurality of interconnecting mat tiles each having a plurality of integrated kinetic generators. Each mat tile has interlocking male protrusions and each female recessions to allow for easy assembly and disassembly.

### (2) Description of Related Art Including Information Disclosed Under 37 CFR 1.97 and 1.98

The prior art relates to generator devices. Known floor generators typically utilize photovoltaic cells or have moving panels. These devices lack integrated kinetic generators. Known devices also lack interconnecting mat tiles and contact connectors on all four sides of each tile.

### BRIEF SUMMARY OF THE INVENTION

An embodiment of the disclosure meets the needs presented above by generally comprising a plurality of mat tiles and a power collection terminal. Each mat tile comprises a mat body having a body top side, a body bottom side, a body left side, a body right side, a body upper face, and a body lower face defining a body cavity. Each of the body top side, the body bottom side, the body left side, and the body right side has a male protrusion portion and a female recessed portion. Each male protrusion portion and each female recessed portion is selectively engageable with the male protrusion portions and the female recessed portions of the adjacent mat tile. A plurality of kinetic generators is coupled to the mat body. Each kinetic generator is coupled within the body cavity. A plurality of electrical connectors is coupled to the mat body. The plurality of electrical generators extends through each of the body top side, the body bottom side, the body left side, and the body right side. The plurality of electrical connectors is in operational communication with the plurality of kinetic generators and with the plurality of electrical connectors of the adjacent mat tiles. The power collection terminal comprises a connector having an engagement portion selectively engageable with the female recessed portion of a corner mat tile of the plurality of mat tiles. The connector is in operational communication with the plurality of electrical connectors. A power bank is coupled to the connector. The power bank is in operational communication with the connector to store energy generated by the plurality of kinetic generators.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF SEVERAL VIEWS OF THE DRAWING(S)

The disclosure will be better understood and objects other than those set forth above will become apparent when consideration is given to the following detailed description thereof. Such description makes reference to the annexed drawings wherein:

FIG. 1 is an isometric view of a floor mat electrical generator system according to an embodiment of the disclosure.

FIG. 2 is a top plan view of an embodiment of the disclosure.

FIG. 3 is a side elevation view of an embodiment of the disclosure.

FIG. 4 is a cross-sectional view of an embodiment of the disclosure along the line 4-4 of FIG. 3.

FIG. 5 is an in-use view of an embodiment of the disclosure.

### DETAILED DESCRIPTION OF THE INVENTION

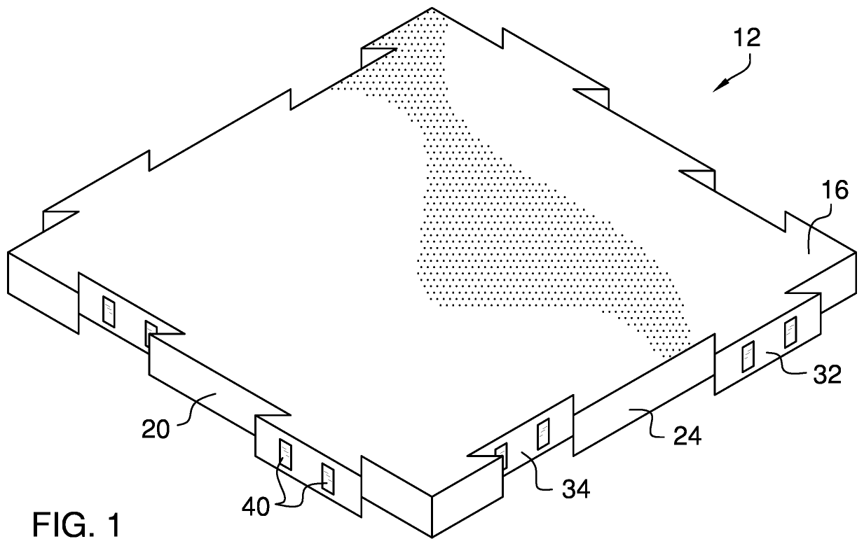

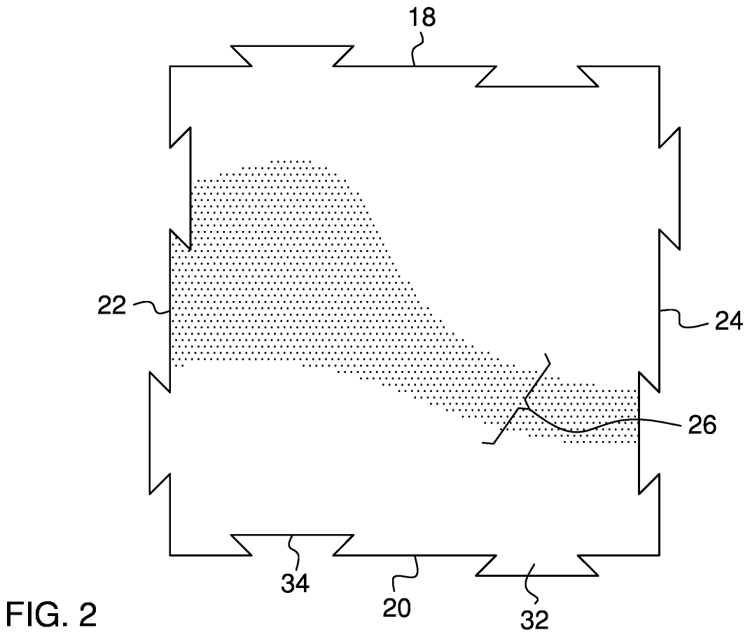

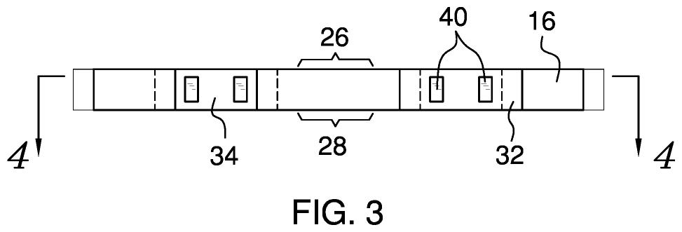

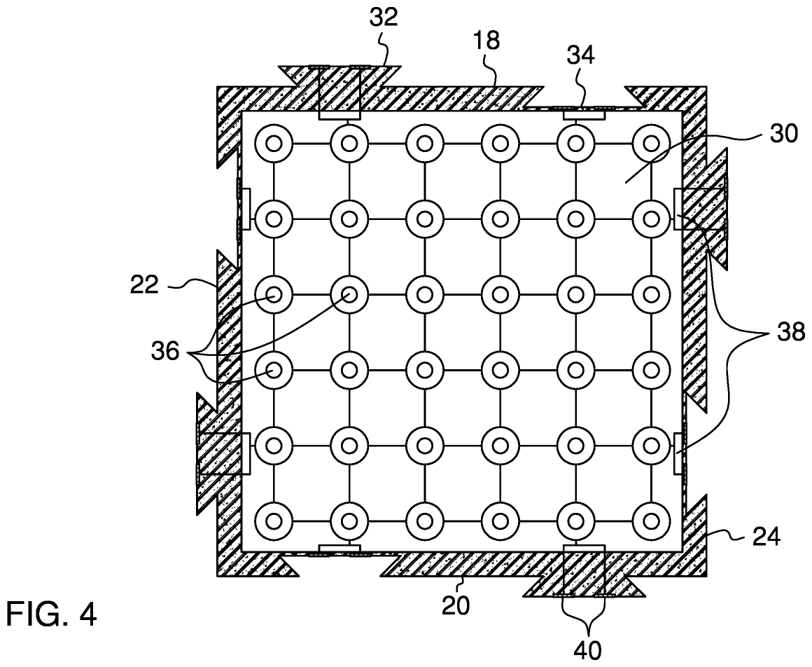

With reference now to the drawings, and in particular to FIGS. 1 through 5 thereof, a new generator device embodying the principles and concepts of an embodiment of the disclosure and generally designated by the reference numeral 10 will be described.

As best illustrated in FIGS. 1 through 5, the floor mat electrical generator system 10 generally comprises a plurality of mat tiles 12 and a power collection terminal 14. Each mat tile 12 comprises a mat body 16 having a body top side 18, a body bottom side 20, a body left side 22, a body right side 24, a body upper face 26, and a body lower face 28 defining a body cavity 30. The body top side 18 of each mat body may be textured to prevent slippage. Each mat body 16 may be an elastically deformable material to allow for compression of the body cavity 30 as it is walked or danced on.

Each of the body top side 18, the body bottom side 20, the body left side 22, and the body right side 24 has a male protrusion portion 32 and a female recessed portion 34. Each male protrusion portion 32 and each female recessed portion 34 may be trapezoidal. Each male protrusion portion 32 and each female recessed portion 34 is selectively engageable with the male protrusion portions 32 and the female recessed portions 34 of the adjacent mat tile 12. The trapezoidal nature of each male protrusion portion 32 and each female recessed portion 34 allows the adjacent mat tiles 12 to interlock and prevent disengagement under translational forces.

A plurality of kinetic generators 36 is coupled to the mat body 16. Each kinetic generator 36 is coupled within the body cavity 30. Each of the plurality of kinetic generators 36 may be a piezoelectric transducer. The plurality of kinetic generators 36 is arranged in a matrix and evenly distributed throughout the body cavity 30 to maximize activation as any portion of the body cavity 30 is compressed.

A plurality of electrical connectors 38 is coupled to the mat body 16. The plurality of electrical generators 38 extends through each of the body top side 18, the body bottom side 20, the body left side 22, and the body right side 24. The plurality of electrical connectors 38 is in operational communication with the plurality of kinetic generators 36 and with the plurality of electrical connectors 38 of the adjacent mat tiles. The plurality of electrical connectors 38 may include a pair of contacts 40 coupled within each male protrusion portion 32 and each female recessed portion 34. Each pair of contacts 40 may be parallel rectangles and each pair of contacts 40 may be magnetized to prevent separation.

The power collection terminal 14 comprises a connector 42 having an engagement portion 44 selectively engageable a corner mat tile 44 of the plurality of mat tiles. The engagement portion 44 may have a connector protrusion 46 to selectively with the female recessed portion 34 of the corner mat tile 44. The connector 42 is in operational communication with the plurality of electrical connectors 38. A power bank 48 is coupled to the connector 42. The power bank 48 is in operational communication with the connector 42 to store energy generated by the plurality of kinetic generators 36. The power bank 48 can collect the energy by charging batteries.

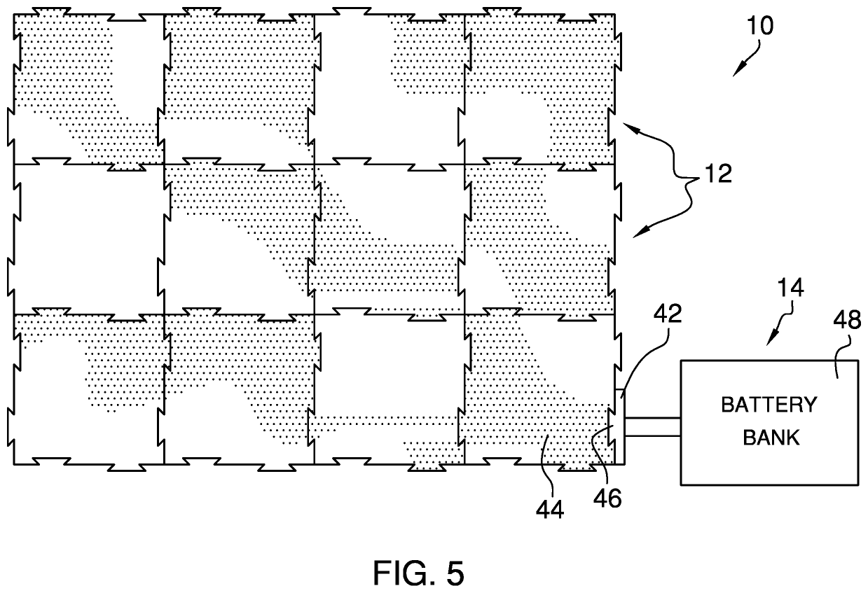

In use, the plurality of mat tiles 12 are interconnected as shown in FIG. 5. The plurality of mat tiles 12 are placed on a dance floor or highly trafficked pedestrian area and the power collection terminal 14 is connected with the connector 42. As users walk or dance on the plurality of mat tiles 12 the body cavities 30 are compressed creating power generation within the plurality of kinetic generators 36 that is then transferred throughout the plurality of electrical connectors 38 to the power bank 48.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

I claim:

1. A floor mat electrical generator system comprising:
a plurality of mat tiles, each mat tile comprising:
a mat body, the mat body having a body top side, a body bottom side, a body left side, a body right side, a body upper face, and a body lower face defining a body cavity, each of the body top side, the body bottom side, the body left side, and the body right side having a male protrusion portion and a female recessed portion, each male protrusion portion and each female recessed portion being selectively engageable with the male protrusion portions and the female recessed portions of the adjacent mat tile;
a plurality of kinetic generators coupled to the mat body, each kinetic generator being coupled within the body cavity; and
a plurality of electrical connectors coupled to the mat body, the plurality of electrical generators extending through each of the body top side, the body bottom side, the body left side, and the body right side, the plurality of electrical connectors being in operational communication with the plurality of kinetic generators and with the plurality of electrical connectors of the adjacent mat tiles; and
a power collection terminal, the power collection terminal comprising:
a connector, the connector having an engagement portion selectively engageable with the female recessed portion of a corner mat tile of the plurality of mat tiles, the connector being in operational communication with the plurality of electrical connectors; and
a power bank coupled to the connector, the power bank being in operational communication with the connector to store energy generated by the plurality of kinetic generators.

2. The floor mat electrical generator system of claim 1 further comprising each of the plurality of kinetic generators being a piezoelectric transducer.

3. The floor mat electrical generator system of claim 1 further comprising each male protrusion portion and each female recessed portion being trapezoidal.

4. The floor mat electrical generator system of claim 1 further comprising the body top side of each mat body being textured.

5. The floor mat electrical generator system of claim 1 further comprising the plurality of kinetic generators being arranged in a matrix and evenly distributed throughout the body cavity.

6. The floor mat electrical generator system of claim 1 further comprising the plurality of electrical connectors including a pair of contacts coupled within each male protrusion portion and each female recessed portion.

7. The floor mat electrical generator system of claim 6 further comprising each pair of contacts being parallel rectangles.

8. The floor mat electrical generator system of claim 6 further comprising each pair of contacts being magnetized.

9. A floor mat electrical generator system comprising:
a plurality of mat tiles, each mat tile comprising:
a mat body, the mat body having a body top side, a body bottom side, a body left side, a body right side, a body upper face, and a body lower face defining a body cavity, the body top side of each mat body being textured, each of the body top side, the body bottom side, the body left side, and the body right side having a male protrusion portion and a female recessed portion, each male protrusion portion and each female recessed portion being trapezoidal, each male protrusion portion and each female recessed portion being selectively engageable with the male protrusion portions and the female recessed portions of the adjacent mat tile;
a plurality of kinetic generators coupled to the mat body, each kinetic generator being coupled within the body cavity, each of the plurality of kinetic generators being a piezoelectric transducer, the plurality of kinetic generators being arranged in a matrix and evenly distributed throughout the body cavity; and
a plurality of electrical connectors coupled to the mat body, the plurality of electrical generators extending through each of the body top side, the body bottom side, the body left side, and the body right side, the plurality of electrical connectors being in operational communication with the plurality of kinetic generators and with the plurality of electrical connectors of the adjacent mat tiles, the plurality of electrical connectors including a pair of contacts coupled within each male protrusion portion and each female recessed portion, each pair of contacts being parallel rectangles, each pair of contacts being magnetized; and
a power collection terminal, the power collection terminal comprising:
a connector, the connector having an engagement portion selectively engageable with the female recessed portion of a corner mat tile of the plurality of mat tiles, the connector being in operational communication with the plurality of electrical connectors; and
a power bank coupled to the connector, the power bank being in operational communication with the connector to store energy generated by the plurality of kinetic generators.
